(19) United States
(12) Patent Application Publication
(10) Pub. No.: US 2025/0371205 A1
(43) Pub. Date: Dec. 4, 2025

(54) VARIABLE-GRID SECURING

(71) Applicant: Advanced Construction Robotics, Inc., Allison Park, PA (US)

(72) Inventors: Jay GOWDY, Pittsburgh, PA (US); Mark Renfrew, Pittsburgh, PA (US); John T. Cameron, Wexford, PA (US); Carson T. Carney, Cranberry Township, PA (US); Danielle A. Proctor, Sewickley, PA (US); Stephen M. Muck, Butler, PA (US); Geoffrey K. White, Valencia, PA (US)

(21) Appl. No.: 18/678,150

(22) Filed: May 30, 2024

(51) Int. Cl. G06F 30/13; G06F 3/04842

(52) U.S. Cl. CPC G06F 30/13; G06F 3/04842

(57) ABSTRACT

Variable-grid securing processes, structures produced by variable-grid securing processes, systems for variable-grid securing, and variable-grid-containing structures are disclosed. The variable-grid securing process includes providing members within a first member set and a second member set, and securing a first portion of the members within the first member set to a second portion of the members within the second member set. The securing is based upon predetermined parameters and updated parameters, the updated parameters applying input captured by analyzing the members. Structures produced by the variable-grid securing process and variable-grid-containing structures are produced by the analyzing of the members. The systems for variable-grid securing use the variable-grid securing process.

### FIELD OF THE INVENTION

The present invention is directed to autonomous and semi-autonomous systems and processes, as well as the structures produced by them. More particularly, the present invention is directed to variable-grid securing processes, structures produced by variable-grid securing processes, systems for variable-grid securing, and variable-grid-containing structures.

### BACKGROUND OF THE INVENTION

Known robots, machines, and sensors rely upon local analysis for executing algorithms to operate in unknown physical conditions. Such algorithms are within the category of “Simultaneous Localization and Mapping” (SLAM) techniques, which are dependent upon predetermined mathematical relationships. The algorithms, as well as systems and processes using them, can suffer from drawbacks of not improving efficiency over time, not incorporating learnings from other environments or conditions, being too reliant upon human input to address certain high-level issues, or combinations thereof. Exclusive use of SLAM techniques also can accumulate localization errors causing substantial deviation from actual values, can lose position within a map causing localization failure or have other challenges.

Systems, structures, and processes that show one or more improvements in comparison to the prior art would be desirable in the art.

### BRIEF DESCRIPTION OF THE INVENTION

In an embodiment, a variable-grid securing process includes providing members within a first member set and a second member set, a majority of the members in the first member set intersecting the members in the second member set, and securing a first portion of the members within the first member set to a second portion of the members within the second member set by using an execution plan. The securing using the execution plan is based upon predetermined parameters and updated parameters, the updated parameters applying input captured by analyzing the members.

In another embodiment, a system for variable-grid securing includes an analytical device for analyzing members within a first member set and a second member set, a majority of the members in the first member set intersecting the members in the second member set, and a securing device for securing a first portion of the members within the first member set to a second portion of the members within the second member set by using an execution plan. The securing of the execution plan is based upon predetermined parameters and updated parameters, the updated parameters applying input captured by the analyzing of the members using the analytical device.

In another embodiment, a grid-containing structure includes members within a first member set and a second member set, a majority of the members in the first member set intersecting the members in the second member set, and securing devices securing a first portion of the members within the first member set to a second portion of the members within the second member set. The securing devices are positioned based upon predetermined parameters and updated parameters, the updated parameters applying input captured by analyzing the members using an analytical device.

Other features and advantages of the present invention will be apparent from the following more detailed description, taken in conjunction with the accompanying drawings which illustrate, by way of example, the principles of the invention.

### BRIEF DESCRIPTION OF THE DRAWINGS

FIG. 1 shows a process of producing a grid-containing structure, specifically shown as a bridge, produced by a system for variable grid-securing, according to embodiments of the disclosure.

FIG. 2 shows a floor in a building, the floor being a grid-containing structure produced by a system for variable grid-securing, according to embodiments of the disclosure.

FIG. 3 shows a deck, the deck being a grid-containing structure produced by a system for variable grid-securing, according to embodiments of the disclosure.

FIG. 4 shows a textile, the textile being a grid-containing structure produced by a system for variable grid-securing, according to embodiments of the disclosure.

FIG. 5 shows members analyzed and boundary changes identified within a process of producing a grid-containing structure, according to embodiments of the disclosure.

FIG. 6 shows input captured by analyzing within a process of producing a grid-containing structure, according to an embodiment of the disclosure.

FIG. 7 shows input captured by analyzing within a process of producing a grid-containing structure, according to an embodiment of the disclosure.

FIG. 8 shows input captured by analyzing within a process of producing a grid-containing structure, according to an embodiment of the disclosure.

FIG. 9 shows input captured by analyzing within a process of producing a grid-containing structure, according to an embodiment of the disclosure.

FIG. 10 shows input captured by analyzing and boundary changes identified within a process of producing a grid-containing structure, according to an embodiment of the disclosure.

FIG. 11 shows input captured by analyzing within a process of producing a grid-containing structure, according to an embodiment of the disclosure.

FIG. 12 shows input captured by analyzing within a process of producing a grid-containing structure, according to an embodiment of the disclosure.

FIG. 13 shows a revised grid map within a process of producing a grid-containing structure, according to an embodiment of the disclosure.

FIG. 14 shows all intersections secured during a process of producing a grid-containing structure, according to an embodiment of the disclosure.

FIG. 15 shows intersections secured in a checker-board pattern during a process of producing a grid-containing structure, according to an embodiment of the disclosure.

FIG. 16 shows a minority of intersections secured during a process of producing a grid-containing structure, according to an embodiment of the disclosure.

Wherever possible, the same reference numbers will be used throughout the drawings to represent the same parts.

### DETAILED DESCRIPTION OF THE INVENTION

Provided are variable-grid securing processes, structures produced by variable-grid securing processes, systems for variable-grid securing, and variable-grid-containing structures, according to embodiments of the disclosure. Embodiments of the present disclosure, for example, in comparison to concepts failing to include one or more of the features disclosed herein, permit improvements over existing technology, for example, U.S. Pat. No. 10,061,323, entitled “Autonomous Apparatus and System for Repetitive Tasks in Construction Project” and U.S. Pat. No. 10,597,264, entitled “Semi-Autonomous System for Carrying and Placing Elongate Objects,” each of which are incorporated by reference in their entirety, permit efficiency increases, incorporate learnings (for example, local, iterative, and global), adjust to environmental variations/conditions, apply human input, reduce or eliminate localization errors, reduce or eliminate position identification failures, enhance data point inclusion, reduce noise, address other challenges, allows sharing of information between referenced autonomous systems and/or units, provides flexibility as to where and how overall computational tasks are distributed, allows for inclusion of other systems (robotic or otherwise) and sensors configured to perform tasks unrelated to the primary operations of the systems disclosed herein, or combinations thereof.

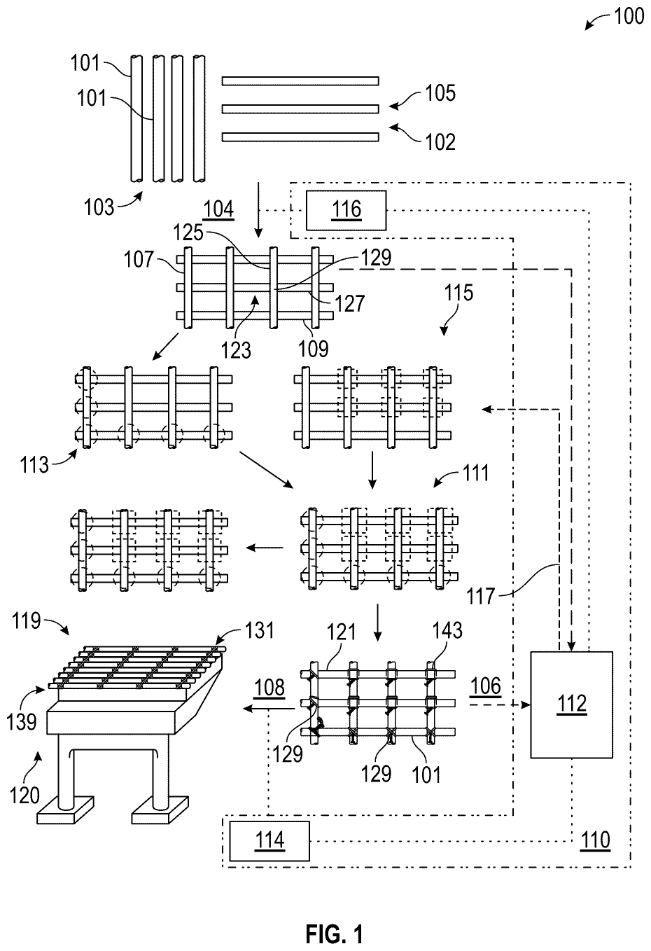

Referring to FIG. 1-16, according to an embodiment, a variable-grid securing process 100 includes providing (step 102) members 101 within a first member set 103 and a second member set 105, positioning (step 104) a first portion 107 of the members 101 within the first member set 103 to a second portion 109 of the members 101 within the second member set 105 and securing (step 108) by using an execution plan 111 (for example, a grid plan, a pattern, a map, or other design plan). The execution plan 111 is based upon predetermined parameters 113 and updated parameters 115. The term “variable” refers to being at least partially inconsistent, for example, without being perfect in relative position of each and every one of the members 101. The term “grid” refers to an arrangement of a plurality of the members 101, particularly, the first member set 103 in conjunction with the second member set 105, and is not further limited.

The updated parameters 115 apply input 117 captured by analyzing (step 106) the members 101, intersections 129 of the members 101, or other suitable features. The analyzing (step 106) is performed through any analytical device 112 or combinations of devices capable of capturing information useful in performing the variable-grid securing process 100. Examples of functionality of the analytical device 112 include three-dimensional sensing, force-based or tactile sensing, dimensional analysis, visual data capture, spectroscopic analysis (for example, to capture composition using x-ray fluorescence Raman spectroscopy, FT-IR, or other similar techniques), thermal analysis, light analysis, or combinations thereof. The functionality of the analytical device 112 is static, for example, with the information being captured at a certain region once, and/or dynamic, with the information being captured over time.

In one embodiment with a plurality of the analytical devices 112, data is combined from each of the devices to allow for the detection of or improvement of the members 101 and/or the intersections 129 of the members 101. For example, in a further embodiment, the same characteristics are measured, such as, distance relative to a point of origin, allowing for combination into a single point-of-view, allowing to reinforce valid signals and reject invalid measurement noise using common techniques, such as, probabilistic occupancy grids or convolution filters. Additionally or alternatively, in one embodiment, different characteristics are measured, such as, information from a three-dimensional sensor with a spectroscopic device and a visual data capturing device, allowing alignment or interpolation between the information with respect to space and time that would otherwise have such information considered separately using common techniques, such as, belief propagation or evidence grids.

In embodiments with the functionality being dynamic, the individual identification of information captured and the changes between the information captured are able to be used.

The securing (step 108) using the execution plan 111 is based upon the predetermined parameters 113 and the updated parameters 115, the predetermined parameters 113 and/or the updated parameters 115 being characteristics, repeatable patterns, grid maps, or combinations thereof, providing allowable/permissible and/or prohibited/impermissible elements for the execution plan 111. The execution plan 111 defines sequences of actions, such as where and/or how the securing (step 108) should or should not be performed, and in some embodiments, where the analyzing (step 106) and/or the positioning (step 104) should or should not be re-performed or further performed.

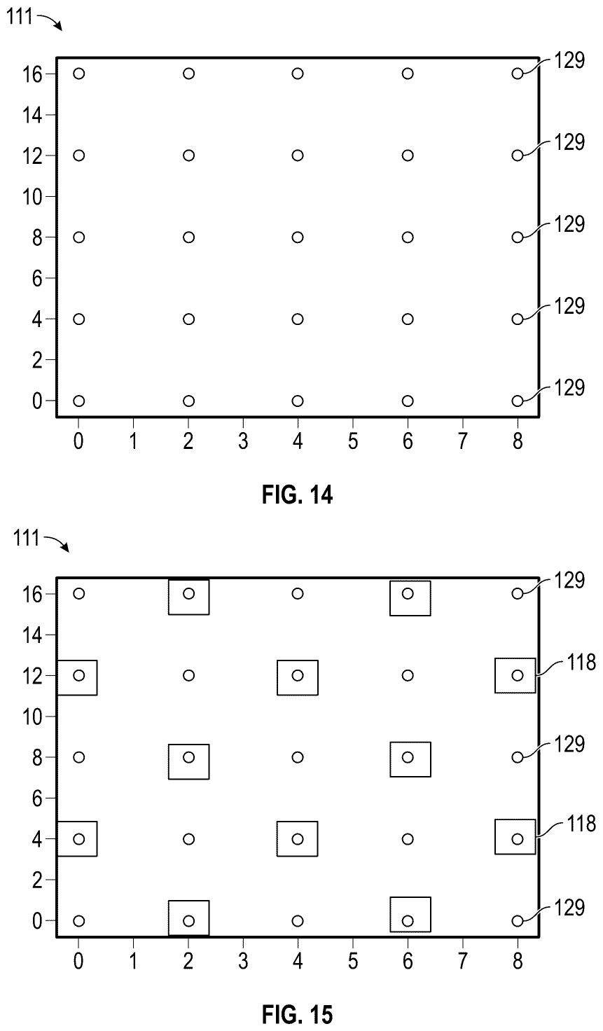

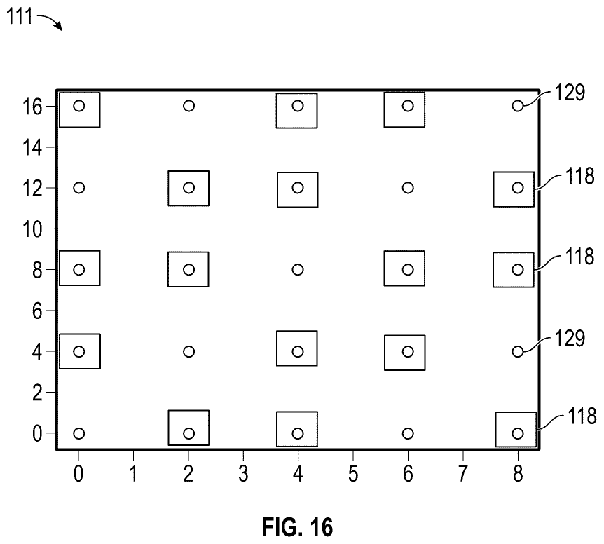

Referring to FIG. 14, in one embodiment, the securing (step 108), according to the execution plan 111, is performed on between 80% and up to 100%, specifically 100%, of the intersections 129. Referring to FIG. 15, in one embodiment, the securing (step 108), according to the execution plan 111, is only performed on between 40% and 60%, specifically 48%, of the intersections 129 (for example, in a checker-board pattern), with the remaining being unsecured intersections 118. Referring to FIG. 16, in one embodiment, the securing (step 108), according to the execution plan 111, is only performed on between 30% and 40%, specifically 32%, of the intersections 129, with the remaining being the unsecured intersections 118.

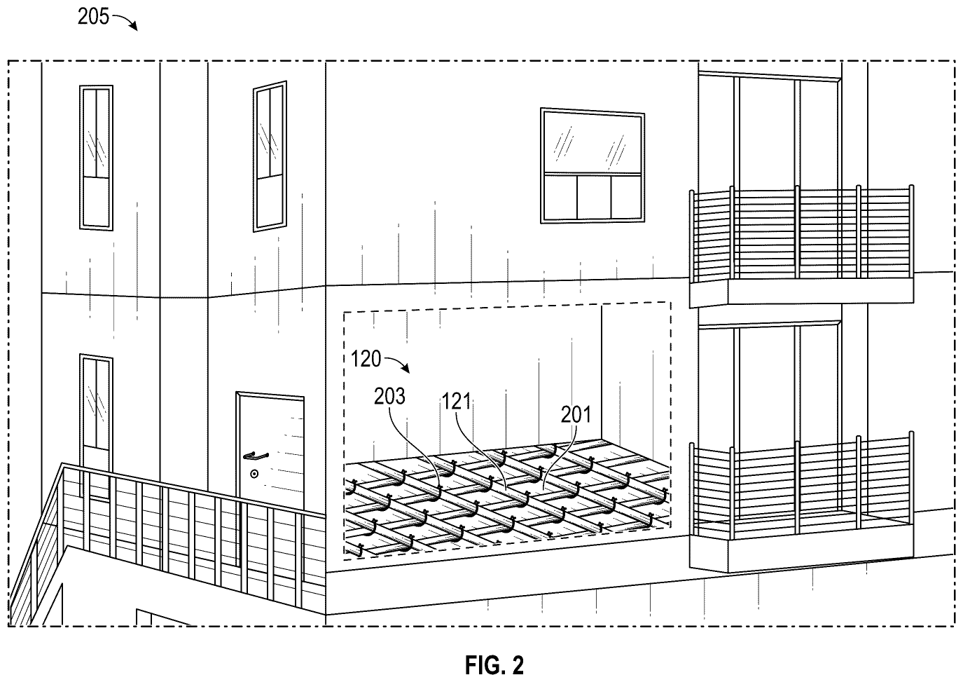

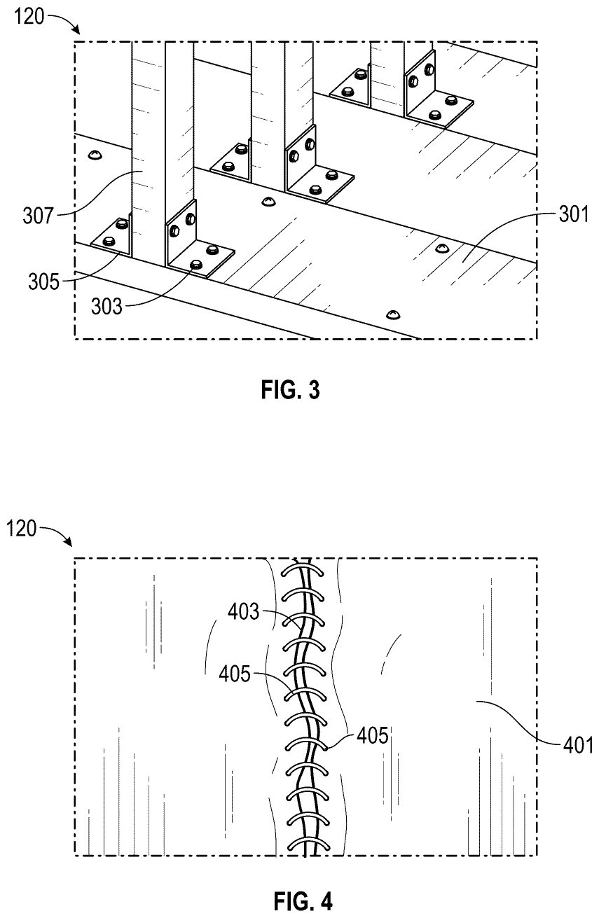

The variable-grid securing process 100 produces a grid-containing structure 120 (or a plurality of the grid-containing structures 120). The grid-containing structure 120 is capable of being a portion of or all of a bridge 119 (see FIG. 1), a floor 201 (see FIG. 2), a building 205 (see FIG. 2), a deck 301 (see FIG. 3), textiles 401 (see FIG. 4), a wall, a roof, multi-floor building construction, a foundation, a column, a reinforced concrete wall, a pre-tied rebar cage, a frame/framing, a mesh structure, a cross-stich pattern, a fiberglass pattern, a carbon-fiber pattern, a nano-tech grid structure, or combinations thereof. In general, the variable-grid securing process 100 is capable of being applied to any intersecting pattern.

Referring again to FIG. 1, in one embodiment, the variable-grid securing process 100 and a system 110 for performing the variable-grid securing process 100 are configured for a plurality of the grid-containing structures 120, with the individual types differing, for example, with a first being the bridge 119 and the second being a roadway section (not shown). In a further embodiment, relevant meta-data, such as, spatially-specific information, on the type or types of the intersections 129 for the grid-containing structures 120 are retained and/or used in the variable-grid securing process 100.

In one embodiment, the variable-grid securing process 100 is performed by the system 110. The system 110 includes the analytical device 112 (or a plurality of the analytical devices 112) for identifying position of the members 101 within the first member set 103 and the second member set 105. Alternatively, the analytical device 112 is separate from the system 110, yet able to perform the analyzing (step 106), for example, with a drone, balloon, or blimp hovering above.

The system 110 further includes a securing device 114 (or a plurality of the securing devices 114) for the securing (step 108) of the first portion 107 of the members 101 within the first member set 103 to the second portion 109 of the members 101 within the second member set 105 by using the execution plan 111. The first portion 107 and/or the second portion 109 are, respectively, the entirety of the first member set 103 and/or the second member set 105, a majority of the first member set 103 and/or the second member set 105, at least 40% of the first member set 103 and/or the second member set 105, at least 20% of the first member set 103 and/or the second member set 105, or any suitable combination, sub-combination, range, or sub-range therein.

Examples of the securing device 114 include mechanical and/or powered tie guns, welders, screwdrivers, hammers, staple guns, pneumatically-driven tools, adhesive tubes, or combinations thereof.

The securing (step 108) is based upon the predetermined parameters 113 and the updated parameters 115, the updated parameters 115 applying the input 117 captured by the analyzing (step 106) of the members 101 using the analytical device 112. The analytical device 112 and the securing device 114 are one device, two devices, physically connected, physically separate, removably connected, permanently connected, at the same site (for example, within 1,000 feet of each other), not at the same site (for example, being more than 1,000 feet apart), linked for sending/receiving of data, or not linked but capable of sending/receiving data through separate storage devices. In an alternative embodiment, the securing (step 108) is partially or completely performed by a human following the updated parameters 115 to guide the securing (step 108), for example, communicated to the securing device 114 and/or communicated to a separate device, such as a cellular telephone, a tablet, a watch, handheld or wearable computers, augmented or virtual-reality devices, or other device capable of sending and/or receiving location data.

Additionally or alternatively, in one embodiment, the positioning (step 104) is performed by a positioning device 116 within the system 110 or operated in conjunction with the system 110. The positioning (step 104) is based upon the predetermined parameters 113 and the updated parameters 115, the updated parameters 115 applying the input 117 captured by the analyzing (step 106) of the members 101 using the analytical device 112.

The analytical device 112 and the positioning device 116 are one device, two devices, physically connected, physically separate, removably connected, permanently connected, at the same site (for example, within 1,000 feet of each other), not at the same site (for example, being more than 1,000 feet apart), linked for sending/receiving of data, or not linked but capable of sending/receiving data through separate storage devices.

Depending upon the grid-containing structure 120, the members 101 are selected from the group consisting of rebar 121 (see FIGS. 1 and 2), wood planks 305 and/or supports 307 (see FIG. 3), threads 405 (see FIG. 4), mesh reinforcement, beams, girders, or combinations thereof.

Referring to FIGS. 1 and 2, the rebar 121 is any suitable material providing tensile strength. Suitable materials include galvanized steel, stainless steel, fiberglass, epoxy-coated materials, metals, metallic materials, or combinations thereof. The rebar 121 is standard or custom, for example, having dimensions/properties shown below or within a suitable range corresponding with the unit of measure, within 1%, within 2%, within 3%, within 4%, or within 5%, whether above or below the identified value:

TABLE 1

| | | Weight | Mass per | | | | |
|---|---|---|---|---|---|---|---|
| | “Soft” | per unit | unit | Nominal | Nominal | Nominal | Nominal |
| Imperial | Metric | length | length | diameter | diameter | Area | Area |
| Bar Size | Size | (lb/ft) | (kg/m) | (in) | (mm) | (in²) | (mm²) |
| #3 | #10 | 0.376 | 0.561 | 0.375 | 9.525 | 0.11 | 71 |
| #4 | #13 | 0.668 | 0.996 | 0.500 | 12.7 | 0.2 | 129 |
| #5 | #16 | 1.043 | 1.556 | 0.625 | 15.875 | 0.31 | 200 |
| #6 | #19 | 1.502 | 2.24 | 0.750 | 19.05 | 0.44 | 284 |
| #7 | #22 | 2.044 | 3.049 | 0.875 | 22.225 | 0.6 | 387 |
| #8 | #25 | 2.67 | 3.982 | 1.000 | 25.4 | 0.79 | 509 |
| #9 | #29 | 3.4 | 5.071 | 1.128 | 28.650 | 1 | 645 |
| #10 | #32 | 4.303 | 6.418 | 1.27 | 32.26 | 1.27 | 819 |
| #11 | #36 | 5.313 | 7.924 | 1.41 | 35.81 | 1.56 | 1006 |
| #14 | #43 | 7.65 | 11.41 | 1.693 | 43 | 2.25 | 1452 |
| #18 | #57 | 13.6 | 20.284 | 2.257 | 57.33 | 4 | 2581 |

Suitable dimensions for the rebar 121 further include lengths of greater than 1 meter, greater than 2 meters, greater than 5 meters, greater than 10 meters, greater than 15 meters, greater than 20 meters, between 1 and 20 meters, between 5 and 20 meters, between 10 and 20 meters, between 15 and 20 meters, between 1 and 10 meters, between 2 and 10 meters, between 5 and 10 meters, or any suitable combination, sub-combination, range, or sub-range therein.

The rebar 121 is generally straight or formed (pre-bent), for example, as or including a J-hook, truss rebar shaped, ladle-shaped, semi-S shaped, flanged, haunch bar, L-bent, U-bent, Unistrut U-bent, V-wing bent, ninety-degree bent, less than ninety-degree bent, greater than ninety-degree bent, 180-degree bent, two-leg bent, offset-and-parallel-leg bent, angled-and-perpendicular-leg bent, complex bent, or a combination thereof.

Referring again to FIG. 1, the providing (step 102) of the members 101 includes the positioning (step 104) of the members 101 for the analyzing (step 106) and the securing (step 108). In one embodiment, the securing (step 108) occurs after the analyzing (step 106). Additionally or alternatively, the analyzing (step 106) occurs after or while the securing (step 108) occurs.

The positioning (step 104) of the members 101 is in any suitable intersecting arrangement having an angle 123 between the members 101, for example, with the member 101 being identifiable as longitudinal members 125 and transverse members 127 to form the intersections 129.

In some embodiments, a plurality, or in further embodiments, a majority, of the members 101 in the first member set 103 are at the angle 123 compared to the members 101 in the second member set 105. The angle 123, measurable from any orientation generally within the same or parallel planes, is between 5 degrees and as high as 90 degrees, between 15 degrees and as high as 90 degrees, between 30 degrees and as high as 90 degrees, between 45 degrees and as high as 90 degrees, between 60 degrees and as high as 90 degrees, between 75 degrees and as high as 90 degrees, greater than 15 degrees, greater than 30 degrees, greater than 45 degrees, greater than 60 degrees, greater than 75 degrees, or any suitable combination, sub-combination, range, or sub-range therein. As will be appreciated by those skilled in the art, the reference angles include complementary angles, for example, with a reference to 30 degrees including the complementary angle of 120 degrees, based upon the opposite frame of reference.

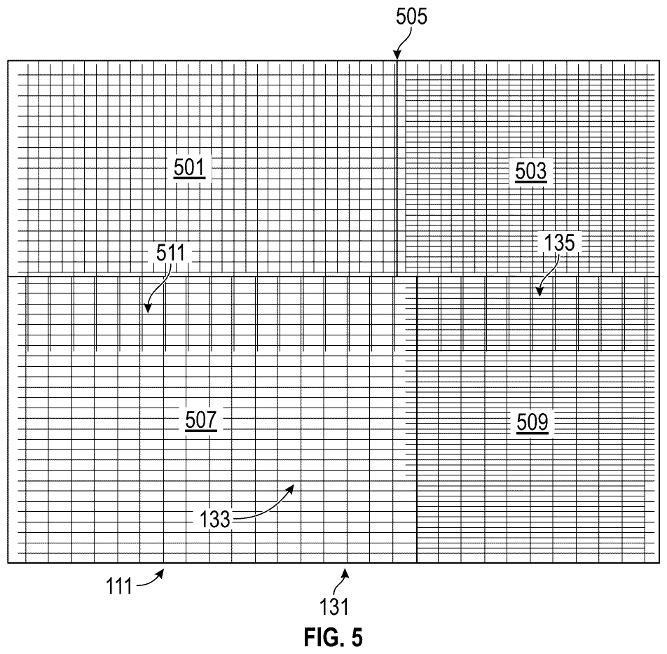

Suitable arrangements are or include a single-level pattern 139 (FIG. 1), a rectilinear pattern 131 (FIG. 5, having all straight or generally straight lines), a lattice pattern 133 (FIG. 5, having the members 101 cross each other), an interrupted linear pattern 135 (FIG. 5, having some of the members 101 discontinue), an inconsistent pattern, a multi-level pattern, a consistent pattern, a herringbone pattern, a pinwheel pattern, a basketweave pattern, a half-basketweave pattern, a stacked bond pattern, a running bond pattern, whorled pattern, or a combination thereof.

The securing (step 108) is performed using one or more securing devices 114. In various embodiments, the securing device 114 include ties 143 (see FIG. 1), spot-welds 203 (see FIG. 2), fasteners 303 (see FIG. 3), stiches 403 (see FIG. 4), shear connectors (for example, studs and/or mud hooks), wires, magnets, adhesives, solders, concrete extrusions, pastes, screws, nails, clamps, or combinations thereof. Suitable types of the securing devices 114 include snaps, single-wrap-and-twists (single-snaps), wall-ties, double-strands, saddles, saddles-with-twists, crosses, or combinations thereof.

In one embodiment, the securing (step 108) occurs and/or does not occur based upon predetermined parameters, such as, the type of the members 101, the type of the intersections 129, the type of the securing devices 114, the type of the grid-containing structure 120, or other suitable segmentation. For example, in one embodiment, the process 100 includes the system 110 executing the securing (step 108) in an incomplete manner (such as, excluding skipping/excluding two of the intersections 129, skipping/excluding one or more of the members 101, or skipping/excluding specific combinations of the types).

Referring to FIG. 3, in one embodiment, the deck 301 includes the wood (or composite) planks 305 and/or the supports 307 instead of the rebar 121. In addition, the deck 301 includes the fasteners 303 as the securing devices 114. As will be appreciated by those skilled in the art, suitable aspects disclosed with reference to the rebar 121 and/or the securing devices 114 are able to be applied to the deck 301, for example, in performing the variable-grid securing process 100. Additional and differentiated embodiments associated with the deck 301, include the fasteners 303 being positioned within the wood planks 305 and/or the supports 307, in contrast to the embodiments with the rebar 121, especially those relying upon the ties 143.

Referring to FIG. 4, in one embodiment, the textiles 401 includes the threads 405 instead of the rebar 121. In addition, the textiles 401 include the stiches 403 as the securing devices 114. As will be appreciated by those skilled in the art, suitable aspects disclosed with reference to the rebar 121 and/or the securing devices 114 are able to be applied to the textiles 401, for example, in performing the variable-grid securing process 100. Additional and differentiated embodiments associated with the textiles 401, include the stiches 403 being positioned within the threads 405, in contrast to the embodiments with the rebar 121 that are generally rigid and not appreciably moving in response to the ties 143.

Referring again to FIG. 1, according to various embodiments, the securing (108) is performed using any suitable techniques. The securing (108) is performed entirely autonomously, semi-autonomously, in parallel, in sequence, consistently, inconsistently, or based upon any desired operating protocol, for example, based upon the execution plan 111. In one embodiment, the securing (step 108) is at a first set of cycles corresponding with a range. The range is, for example, between 20 Hz and 60 Hz, 30 Hz and 60 Hz, 20 Hz and 50 Hz, 30 Hz and 50 Hz, 20 Hz and 40 Hz, 30 Hz and 40 Hz, 20 Hz and 30 Hz, 40 Hz and 60 Hz, 50 Hz and 60 Hz, 40 Hz and 50 Hz, or any suitable combination, sub-combination, range, or sub-range therein.

The analyzing (step 106) occurs at a second set of cycles. The information captured by the analyzing (step 106) is able to be used in real-time or discrete bundles over time. In one embodiment, the second set of cycles corresponds with the first set of cycles, for example, with the analyzing (step 106) occurring at a more rapid rate than the securing (step 108) or the positioning (step 104), or the analyzing (step 106) occurring at the same rate as the securing (108) or the positioning (step 104). Suitable embodiments with the analyzing (step 106) occurring at a more rapid rate than the securing (step 104) include the analyzing (step 106) being between 0.5 Hz and 5 Hz, 0.5 Hz and 10 Hz, 0.5 Hz and 20 Hz, 0.5 Hz and 30 Hz, 0.5 Hz and 40 Hz, 0.5 Hz and 50 Hz, 0.5 Hz and 60 Hz, 1 Hz and 5 Hz, 1 Hz and 10 Hz, 1 Hz and 20 Hz, 1 Hz and 30 Hz, 1 Hz and 40 Hz, 1 Hz and 50 Hz, 1 Hz and 60 Hz, 5 Hz and 10 Hz, 5 Hz and 20 Hz, 5 Hz and 30 Hz, 5 Hz and 40 Hz, 5 Hz and 50 Hz, 5 Hz and 60 Hz, 10 Hz and 20 Hz, 10 Hz and 30 Hz, 10 Hz and 40 Hz, 10 Hz and 50 Hz, 10 Hz and 60 Hz, or any suitable combination, sub-combination, range, or sub-range therein.

According to various embodiments, the analyzing (step 106) of the members 101 includes identifying missing members compared to the predetermined parameters 113, identifying missing intersections (or extra) compared to the predetermined parameters 113, identifying unexpected spacing between two or more of the members 101, identifying unexpected positioning of one or more of the members 101, for example, being too close, too far from a bridge deck 153, such as shown in FIG. 1, and/or being bent, or being broken, identifying foreign members, identifying non-member objects, for example, shear studs, characterizing the boundary changes 505 from the predetermined parameters 113, or combinations thereof. Further or alternative embodiments include the analyzing (step 106) identifying non-planar surfaces (for example, having a sloped, concave, convex, rough, smooth, and/or inconsistent topology, such as on a bottom deck of the bridge 119).

In one embodiment, the analyzing (step 106) uses statistics and/or mathematical principles to identify and accommodate errors or problems encountered. For example, the statistics and/or the mathematical principles score based upon the predetermined parameters 113 and/or the updated parameters 115 to identify/characterize the allowable/permissible and/or the prohibited/impermissible elements. Suitable mathematic principles include hidden Markov random fields, boundary estimation (concave or convex hull analysis), conditional random fields, Bayesian networks, convolution neural networks, cyclically repeating function fitting, belief propagation, or combinations thereof.

Referring to FIGS. 5-8, in one embodiment, statistics are generated relating to a first region 501 and a second region 503 of the execution plan 111, with the first region 501 and the second region 503 defining the boundary change(s) 505, for example, by identifying a distinct change. Additional embodiments include further regions, such as a third region 507, a fourth region 509, and/or transitional regions 511. The regions are defined by one or both of the predetermined parameters 113 and the updated parameters 115, with the execution plan 111 performing the positioning (step 104) and/or the securing (step 108) within each of the regions based upon the analyzing (step 106).

As shown in FIG. 5, in one embodiment, the first region 501 differs from the second region 503 by the members 101 being more tightly spaced. The fourth region 509 includes the members 101 being more tightly spaced than the third region 507. The first region 501 and the second region 503 differ from the fourth region 509 by the members 101 in those regions being more tightly spaced. The variation in spacing of the members 101 defined the boundary changes 505.

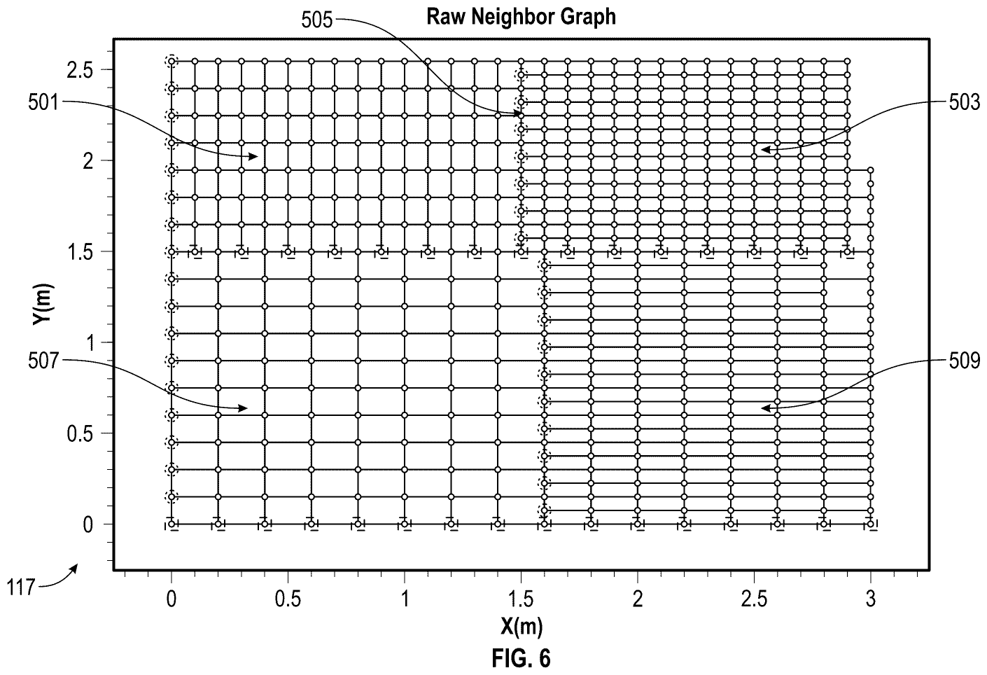

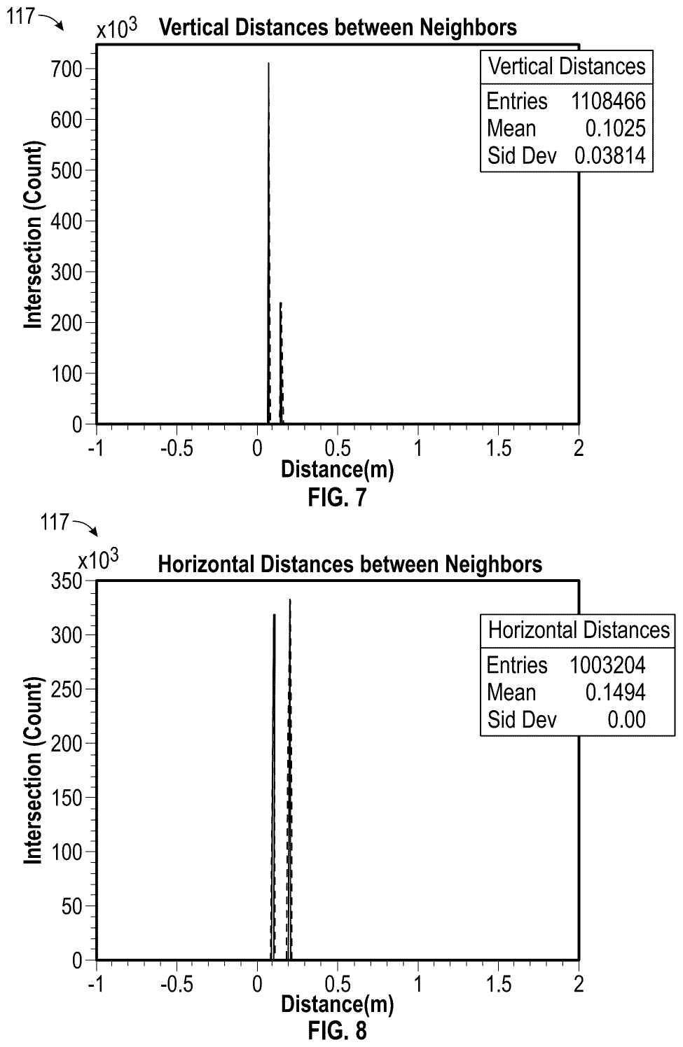

FIG. 6-8 show measurements, specifically distances between the members 101 with counts of the quantity of the members at specific distances, capable of being the input 117 used for the updated parameters 115. FIG. 7 shows measurements for the longitudinal members 125 and FIG. 8 shows measurements of the transverse members 127 to define the boundary change 205 of FIG. 5 between the first region 501 and the second region 503. As will be appreciated, any combination of similar measurements are able to be used in the updated parameters 115.

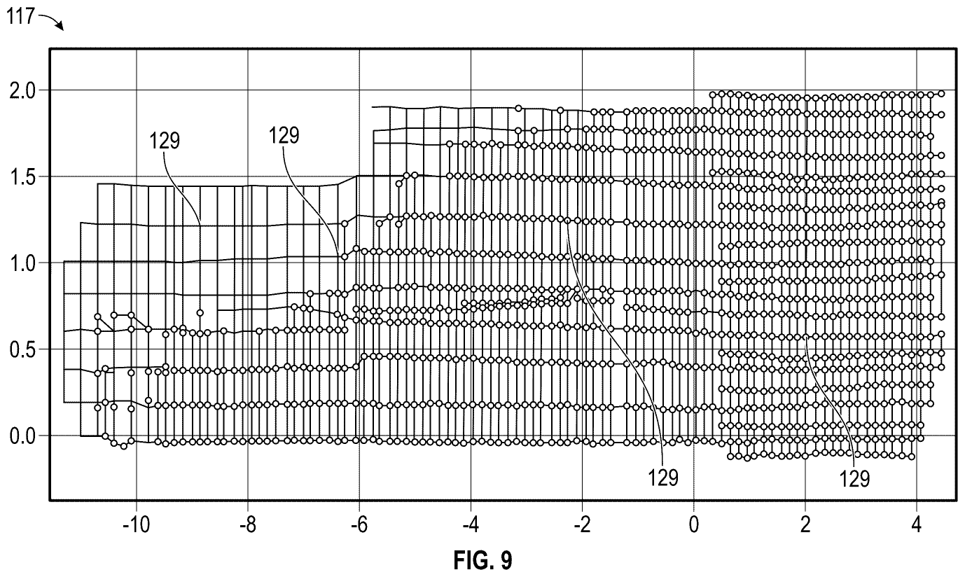

Referring to FIG. 9, in one embodiment, the input 117 captured by the analyzing (step 106) is able to be non-linear, entirely or in parts, complex in geometry, and/or otherwise inconsistent or unreliable without further fitting, scaling (for example, by factors), or correlative efforts. By enhancing data point inclusion, reducing or eliminating use of data from the boundary changes 505, using polygons and simple shapes over unique line segments, noise is reduced in the characterizing of the input 117. Such enhancing allows the securing (step 108) and even the positioning (step 104) to be performed in a forward-looking manner to calculate future impact in different regions based upon current decisions regarding the input 117 for the updated parameters 115.

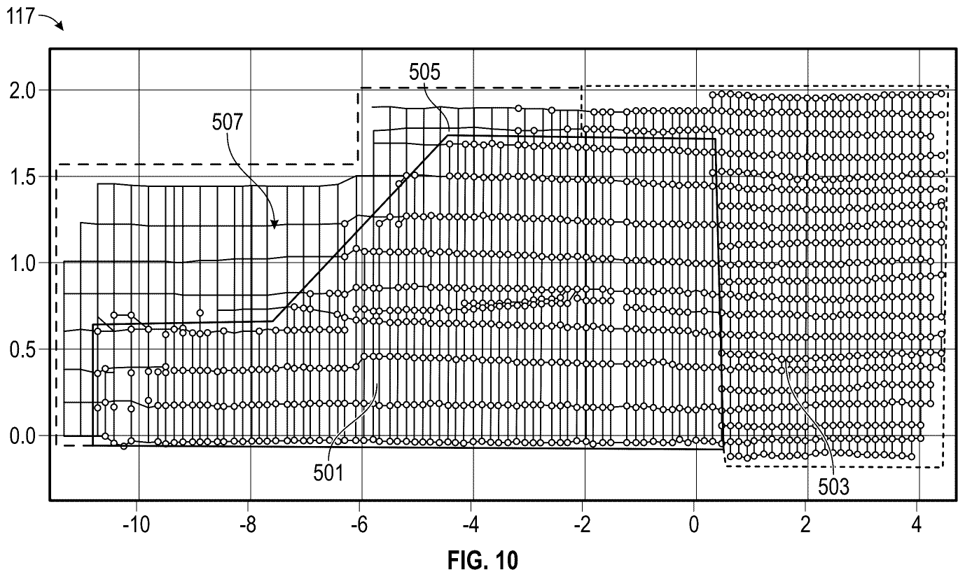

Referring to FIG. 10, in one embodiment, the boundary changes 505 produced from the input 117 include the first region 501 having six sides, with one being diagonal compared to the other five. The boundary changes 505 of FIG. 10 further include the second region 503 having six sides, all being straight, for example, in a rectilinear manner. The boundary changes 505 of FIG. 10 further include the third region 507 being on edges of the input 117, being statistically ignored or discounted in the analyzing (step 106).

In one embodiment, due to the system 110 and/or the variable-grid securing process 100 continuously learning and updating information about the environment, the boundaries of any of the regions-particularly when they are at the extents of where it has observed-aren't ever necessarily considered “fixed”. The system 110 is able to become more “confident” in defining the boundaries as a result of the iterative updates provided by the analyzing (step 106) based on the input(s) 117 provided.

In another embodiment, the system 110 and/or the variable-grid securing process 100 define regions by enclosing spatial segments, curves, splines, or other geometric primitive or boundary constraint(s), independent of whether the constraints refer to the extent to which the system 110 observed its environment. For example, in a further embodiment, with region boundaries defined by deriving enclosing boundaries based upon positive information, such as, a set of observed intersection. In another embodiment, region boundaries are defined by deriving enclosing boundaries based upon negative information, such as, a set of neighboring, adjacent, or nearby spatial areas that the system 110 has no information or insufficient information about to make a determination. In yet another embodiment, a combination of positive and negative information is used, for example, with common robotics data structures, such as, occupancy grids or evidence grids, allowing regional boundaries to be derived from the analyzing (step 106) of cells within grids that contain positive confirming information of the presence of the intersection(s) 129 (specifically, valid intersections) and negative information indicating the absence of the intersection(s) 129 (specifically, valid intersections), for example, based upon information/values indicating that the system 110 does not have sufficient information to decide either way (such as, for unobserved or under-observed spatial areas) or some combination of information types.

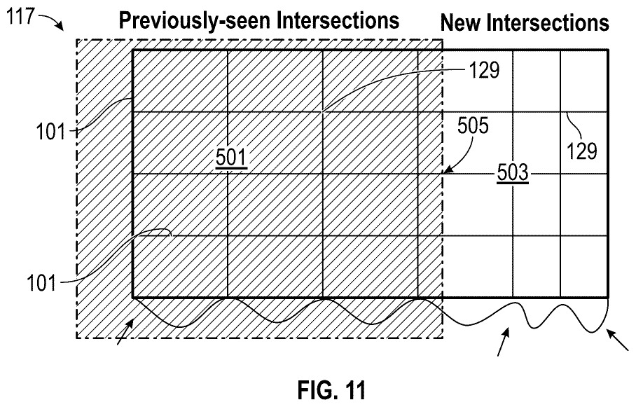

Referring to FIG. 11, in one embodiment, the boundary changes 505 are identified immediately upon transitioning from the first region 501 to the second region 503 based upon the intersections 129 being different in spacing.

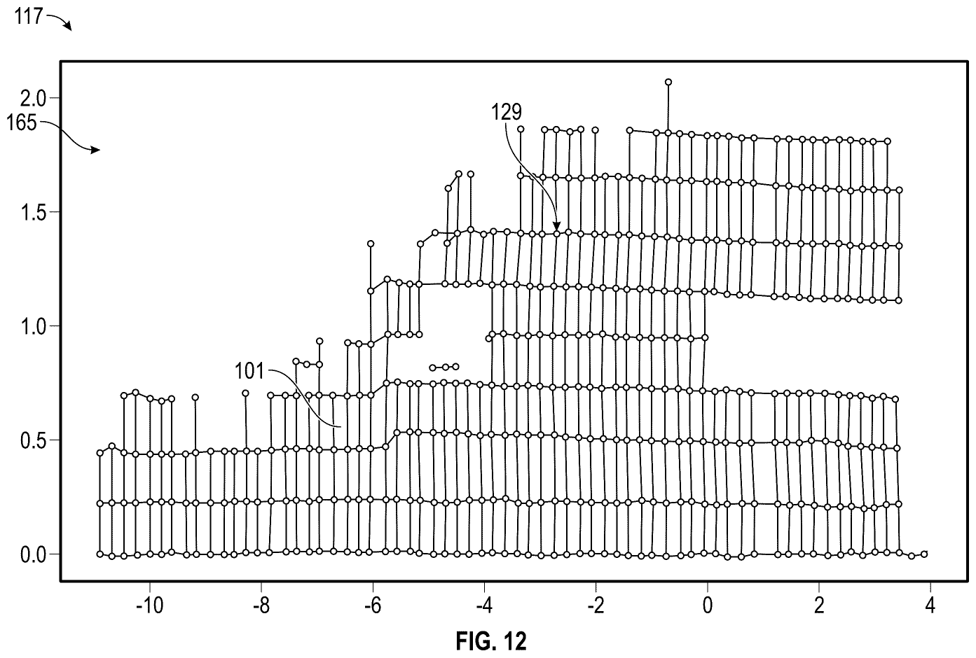

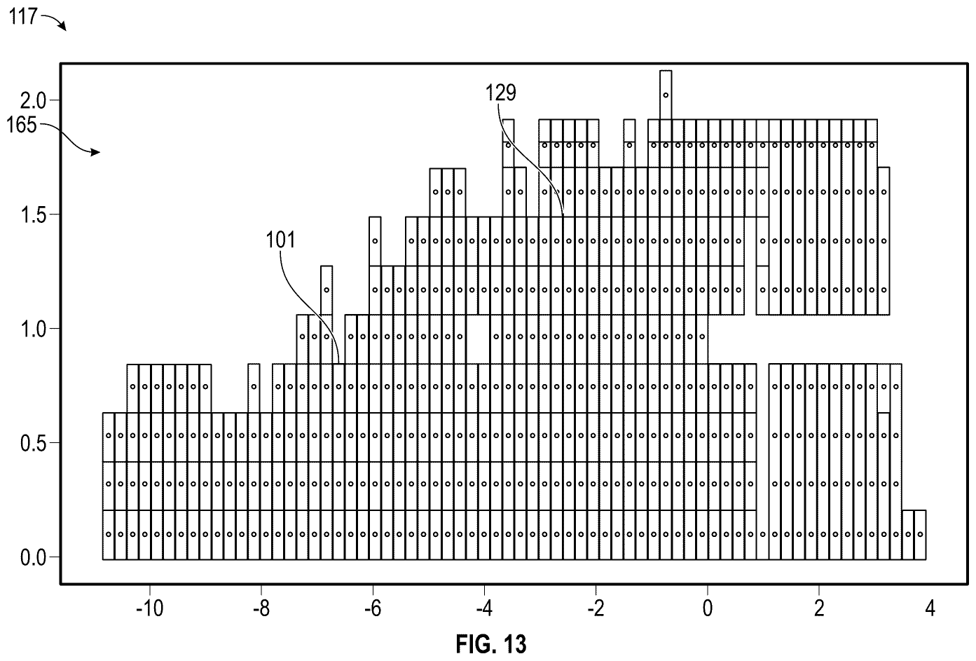

Referring again to FIG. 1, in one embodiment, the process 100 produces a revised grid map 165 (see FIG. 12-13) corresponding with the execution plan 111 being based upon the input 117 from the updated parameters 115. The revised grid map 165 includes or excludes based upon the analyzing (step 106), for example, identifying features disclosed above with reference to FIG. 5 and/or identifying regions where the securing (step 108) occurred.

The revised grid map 165 is able to be used as the predetermined parameters 113 in the future (future predetermined parameters), whether at the same site/location or at one or more future site(s)/location(s). Referring to FIGS. 12-13, in one embodiment, the revised grid map 165 allows improvements to the statistical and/or mathematical models, further driving efficiency and accuracy of the process 100 in the future. For example, in a further embodiment, the revised grid map 165 correlates with the input 117 as shown in FIG. 12 captured by the analyzing (step 106), with the measurements of the members 101 being non-linear and/or inconsistent to produce the revised grid map 165 shown in FIG. 13 in a linear and consistent manner.

In another embodiment, the process 100 includes a decision interface for a human operator, for example, on whether the execution plan 111 incorporates all or portions of the revised grid map 165, the predetermined parameters 113, the updated parameters 115, and the input 117 captured by the analyzing (step 106).

In a specific embodiment of the process 100, a human operator observes that the securing device 114 will be operating in a region prone to difficult operation, for example, due to updating of parameters being unreliable. In such embodiments, the human operator uses an interface to provide additional constraints or confirms information to the system 110 either before the process 100 or a portion of the process 100 or during the process 100 or a portion of the process 100. In a further embodiment, the interface is configured for the human operator to override parameters of the system 110 or a portion of the system 110, whether the parameters are based upon the input 117, the updated parameters 115, the predetermined parameters 113, the execution plan 111, other algorithms, or a combination thereof. Such overriding is capable of being limited to levels of performance, including being permanent until adjusted the human operator, future human operators, or through future algorithms. Additionally or alternatively, such overriding is able to be specific to a single region, persistent for regions with specific parameters, persistent for the intersections 129 having particular parameters, persistent for the members 101 having specific parameters, persistent for entire spatial areas of one or more regions, temporary based upon any such parameters (for example, as defined by the human operator and/or an algorithm), localized based upon any such parameters (for example, as defined by the human operator and/or an algorithm), of a combination thereof.

In another specific embodiment of the present disclosure, the variable-grid securing process 100 is performed, including the positioning (step 104) of the members 101, the analyzing (step 106) of the members 101, and the securing (step 108) of the members 101 by using the execution plan 111 based upon the predetermined parameters 113 and the updated parameters 115. Referring to FIGS. 6-8, the longitudinal members 125 are measured during the analyzing (step 106) to show over about 700,000 of the longitudinal members 125 being positioned less than 0.1 meters apart and about 250,000 of the longitudinal members 125 being positioned between 0.1 and 0.2 meters apart. The transverse members 127 are measured during the analyzing (step 106) to show over about 320,000 of the transverse members 127 being positioned between than 0.05 meters and 0.15 meters apart and about 330,000 of the transverse members 127 being positioned between 0.15 and 0.25 meters apart. Applying the algorithmic principles of belief propagation, noise is reduced.

In yet another specific embodiment of the present disclosure, the variable-grid securing process 100 is performed, including the positioning (step 104) of the members 101, the analyzing (step 106) of the members 101, and the securing (step 108) of the members 101 by using the execution plan 111 based upon the predetermined parameters 113 and the updated parameters 115. Referring to FIGS. 9-10, the analyzing (step 106) of the input 117 of FIG. 9 includes enhanced data point inclusion and use of polygons over unique line segments, with the intersections 129 being filtered by hidden Markov random fields. The boundary changes 505 shown in FIG. 10 are defined by boundary estimation, specifically, with the first region 501 having six sides, with one being diagonal compared to the other five, the second region 503 having six sides, all being straight in a rectilinear manner. By using the filtering by hidden Markov random fields and defining of the boundary changes 505 by boundary estimation, reduction in time for the securing (step 108) is achieved.

In yet another specific embodiment of the present disclosure, the variable-grid securing process 100 is performed, including the positioning (step 104) of the members 101, the analyzing (step 106) of the members 101, and the securing (step 108) of the members 101 by using the execution plan 111 based upon the predetermined parameters 113 and the updated parameters 115. Referring to FIGS. 12-13, the actual location measurements shown in FIG. 12 are used to produce the revised grid map 165 of FIG. 13, the revised grid map 165 having linear and more consistent positioning for the intersections 129 and the members 101. The linearity of the revised grid map 165 allows the prevention of failures due to statistical anomalies.

In some embodiments, a non-transitory computer-readable medium with stored instructions, the instructions when executed by a processor, cause the processor to capture input and compile parameters, thereby forming the execution plan 111. In a further embodiment, the execution plan 111 is displayed, allowing access by the user (for example, a human operator) and/or others (for example, off-site individuals).

In some embodiments, the operations shown in the drawings and described in this specification are computer-implemented systems and methods. This means they are implemented in digital electronic circuitry, or in computer software, firmware, or hardware, including the structures disclosed in this specification or in combinations of one or more of them.

In one embodiment, the operations are implemented as operations performed by a data processing apparatus on data stored on one or more computer-readable storage devices or received from other sources.

In one embodiment, the data processing apparatus, computer, or computing device encompasses apparatus, devices, and machines for processing data, including, by way of example, a programmable processor, a computer, a system on a chip, or multiple ones, or combinations, of the foregoing.

In one embodiment, the apparatus includes special purpose logic circuitry, for example, a central processing unit (CPU), a parallel graphics processing unit (GPU), a field programmable gate array (FPGA) or an application-specific integrated circuit (ASIC).

In one embodiment, the apparatus includes code that creates an execution environment for the computer program in question, for example, code that constitutes processor firmware, a protocol stack, a database management system, an operating system (for example, an operating system or a combination of operating systems), a cross-platform runtime environment, a virtual machine, or a combination of one or more of them.

In one embodiment, the apparatus and execution environment realize various different computing model infrastructures, such as web services, distributed computing and grid computing infrastructures.

As used herein, a “computer program” refers to an executable program of instructions able to be executed on one computer or on multiple computers that are located at one site or distributed across multiple sites and interconnected by a communication network. Generally, a computer also includes, or is operatively coupled to receive data from or transfer data to, or both, one or more mass storage devices for storing data. A computer, or node, is capable of being embedded in another device, for example, a mobile device, a personal digital assistant (PDA), a game console, a Global Positioning System (GPS) receiver, or a portable storage device. Devices suitable for storing computer program instructions and data include non-volatile memory, media and memory devices, including, by way of example, semiconductor memory devices, magnetic disks, and magneto-optical disks. The processor and the memory are capable of being supplemented by, or incorporated in, special-purpose logic circuitry. Additionally, processors for execution of a computer program include, by way of example, both general- and special-purpose microprocessors, and any one or more processors of any kind of digital computer. Generally, a processor receives instructions and data from a read-only memory or a random-access memory or both. The essential elements of a computer are a processor for performing actions in accordance with instructions and one or more memory devices for storing instructions and data.

While the invention has been described with reference to one or more embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

What is claimed is:

1. A variable-grid securing process, comprising:
providing members within a first member set and a second member set, a majority of the members in the first member set intersecting the members in the second member set; and
securing a first portion of the members within the first member set to a second portion of the members within the second member set by using an execution plan;
wherein the securing using the execution plan is based upon predetermined parameters and updated parameters, the updated parameters applying input captured by analyzing the members.

2. The variable-grid securing process of claim 1, wherein the securing occurs at a first set of cycles and the analyzing occurs at a second set of cycles, the second set of cycles being at a more rapid rate than the first set of cycles.

3. The variable-grid securing process of claim 1, wherein the securing includes using a tie.

4. The variable-grid securing process of claim 1, wherein the securing includes using a securing device selected from the group consisting of a magnet, an adhesive, a weld, solder, concrete, a screw, and combinations thereof.

5. The variable-grid securing process of claim 1, wherein the analyzing of the members includes identifying missing members from the predetermined parameters, missing intersections from the predetermined parameters, unexpected spacing between two or more of the members, unexpected positioning of one or more of the members, foreign members, non-member objects, excluded members, or a combination thereof.

6. The variable-grid securing process of claim 1, wherein the analyzing includes characterizing boundary changes from the predetermined parameters.

7. The variable-grid securing process of claim 1, wherein the analyzing includes characterizing boundary changes from the updated parameters.

8. The variable-grid securing process of claim 1, wherein the analyzing includes applying mathematic principles applicable to hidden Markov random fields, boundary estimation, conditional random fields, Bayesian networks, convolutional neural networks, belief propagation, or a combination thereof.

9. The variable-grid securing process of claim 1, comprising providing a decision interface to a human operator and the human operator selecting between two or more decisions.

10. The variable-grid securing process of claim 1, wherein the members are rebar.

11. The variable-grid securing process of claim 1, wherein the members are deck planks, beams, girders, or a combination thereof.

12. The variable-grid securing process of claim 1, wherein the intersecting is at angles between 5 degrees and 90 degrees.

13. The variable-grid securing process of claim 1, further comprising building a revised grid map from the updated parameters, the revised grid map being used as future predetermined parameters for a future variable-grid securing process.

14. The variable-grid securing process of claim 1, further comprising building a revised grid map from the predetermined parameters and the updated parameters, the revised grid map being used as future predetermined parameters for a future variable-grid securing process.

15. The variable-grid securing process of claim 1, further comprising building a revised grid map, the revised grid map including statistics relative to one or both of the predetermined parameters and the updated parameters.

16. The variable-grid securing process of claim 1, further comprising building a revised grid map identifying secured positions within the execution plan.

17. A structure produced by the variable-grid securing process of claim 1, the structure being a bridge.

18. A structure produced by the variable-grid securing process of claim 1, the structure being a building, a floor, a deck, a roof, or a combination thereof.

19. A system for variable-grid securing, the system comprising:
an analytical device for analyzing members within a first member set and a second member set, a majority of the members in the first member set intersecting the members in the second member set; and
a securing device for securing a first portion of the members within the first member set to a second portion of the members within the second member set by using an execution plan;
wherein the securing of the execution plan is based upon predetermined parameters and updated parameters, the updated parameters applying input captured by the analyzing of the members by using the analytical device.

20. A grid-containing structure, comprising:
members within a first member set and a second member set, a majority of the members in the first member set intersecting the members in the second member set; and
securing devices securing a first portion of the members within the first member set to a second portion of the members within the second member set;
wherein the securing devices are positioned based upon predetermined parameters and updated parameters, the updated parameters applying input captured by analyzing the members using an analytical device.
